(19) United States
(12) Patent Application Publication
(10) Pub. No.: US 2021/0296527 A1
(43) Pub. Date: Sep. 23, 2021

(54) NITRIDE SEMICONDUCTOR LIGHT-EMITTING ELEMENT AND METHOD FOR MANUFACTURING SAME

(71) Applicant: NIKKISO CO., LTD., Tokyo (JP)

(72) Inventors: Yusuke MATSUKURA, Ishikawa (JP); Cyril PERNOT, Ishikawa (JP)

(73) Assignee: NIKKISO CO., LTD., Tokyo (JP)

(21) Appl. No.: 17/264,617

(22) PCT Filed: May 24, 2019
(86) PCT No.: PCT/JP2019/020653

§ 371 Date: Jan. 29, 2021

(30) Foreign Application Priority Data
Jul. 31, 2018 (JP) 2018-143418

(51) Int. Cl. H01L 33/06; H01L 33/32; H01L 33/00

(52) U.S. Cl. CPC H01L 33/06; H01L 33/0025; H01L 33/32

(57) ABSTRACT

A nitride semiconductor light-emitting element includes stacked AlGaN-based nitride semiconductors and emits ultraviolet light at a central wavelength of 290 nm to 360 nm. The nitride semiconductor light-emitting element includes an n-type cladding layer comprising n-type AlGaN, and an active layer provided on the n-type cladding layer and comprising a single quantum well structure. The single quantum well structure includes one barrier layer made of AlGaN and one well layer made of AlGaN with an Al composition ratio lower than an Al composition ratio of the AlGaN constituting the one barrier layer.

### TECHNICAL FIELD

The invention relates to a nitride semiconductor light-emitting element and a method for manufacturing the same.

### BACKGROUND ART

Nitride semiconductor light-emitting elements such as light-emitting diodes or laser diodes which emit blue light are known (see, Patent Document 1).

The nitride semiconductor light-emitting element described in Patent Document 1 is a light-emitting element with an emission wavelength of not more than 300 nm to be formed on an AlN-based group III nitride single crystal, and has a high-concentration n-type group III nitride layer, a multiple quantum well structure composed of n-type or i-type group III nitride barrier layers and n-type or i-type group III nitride well layers, an i-type group III nitride final barrier layer, a p-type group III nitride layer, and an electron blocking layer made of a p-type or i-type AlN layer which is provided between the i-type group III nitride final barrier layer and the p-type group III nitride layer and acts as an electron energy barrier for the i-type group III nitride final barrier layer, wherein the i-type group III nitride final barrier layer has a thickness of 2 nm to 10 nm and the n-type or i-type group III nitride well layers have a thickness of not more than 2 nm.

In this way, luminous efficiency of light-emitting elements is conventionally improved by providing a multiple quantum well layer in which multiple quantum well structures are stacked.

### CITATION LIST

### Patent Literature

Patent Document 1: Japanese Patent No. 5641173

### SUMMARY OF INVENTION

### Technical Problem

However, the inventors found that in case of nitride semiconductor light-emitting elements made of AlGaN, luminous efficiency in a specific emission wavelength range is not necessarily improved even when providing multiple quantum well structures, i.e., luminous efficiency can be improved more with the single quantum well structure than with the multiple quantum well structures, depending on the emission wavelength range.

Therefore, it is an object of the invention to provide a nitride semiconductor light-emitting element with improved luminous efficiency in a specific emission wavelength range, and a method for manufacturing the same.

### Solution to Problem

A nitride semiconductor light-emitting element according to an embodiment of the invention includes stacked AlGaN-based nitride semiconductors and is configured to emit ultraviolet light at a central wavelength of 290 nm to 360 nm, and the nitride semiconductor light-emitting element comprises: an n-type cladding layer comprising n-type AlGaN; and an active layer provided on the n-type cladding layer and comprising a single quantum well structure comprising one barrier layer comprising AlGaN and one well layer comprising AlGaN with an Al composition ratio lower than an Al composition ratio of the AlGaN constituting the one barrier layer.

A method for manufacturing a nitride semiconductor light-emitting element in another embodiment of the invention comprises: forming an n-type cladding layer comprising n-type AlGaN on a substrate; and forming, on the n-type cladding layer, an active layer comprising a single quantum well structure comprising one barrier layer comprising AlGaN and one well layer comprising AlGaN with an Al composition ratio lower than an Al composition ratio of the AlGaN constituting the one barrier layer.

### Advantageous Effects of Invention

According to the invention, it is possible to provide a nitride semiconductor light-emitting element with improved luminous efficiency in a specific emission wavelength range, and a method for manufacturing the same.

### BRIEF DESCRIPTION OF DRAWINGS

FIG. 1 is a schematic cross-sectional view showing an example configuration of a nitride semiconductor light-emitting element in an embodiment of the present invention.

FIG. 2 is a diagram illustrating the measurement results of emission output of light-emitting elements in Example and Comparative Examples.

FIG. 3 is a diagram illustrating a relation between emission wavelength and emission output of the light-emitting elements in Example and Comparative Example.

FIG. 4 is a diagram illustrating a relation between emission wavelength and emission output of light-emitting elements in other Comparative Examples.

### DESCRIPTION OF EMBODIMENT

### Embodiment

An embodiment of the invention will be described in reference to the drawings. The embodiment below is described as a preferred example for implementing the invention. Although some part of the embodiment specifically illustrates various technically preferable matters, the technical scope of the invention is not limited to such specific aspects. In addition, a scale ratio of each constituent element in each drawing is not necessarily the same as the actual scale ratio of the nitride semiconductor light-emitting element. In addition, in the following description, “upper/on” or “lower/under” indicates a relative position of one object to another object, and includes not only a state in which the one object is arranged on or under the other object without any third object in-between, but also a state in which the one object is arranged on or under the other object with a third object in-between.

(Configuration of Nitride Semiconductor Light-Emitting Element)

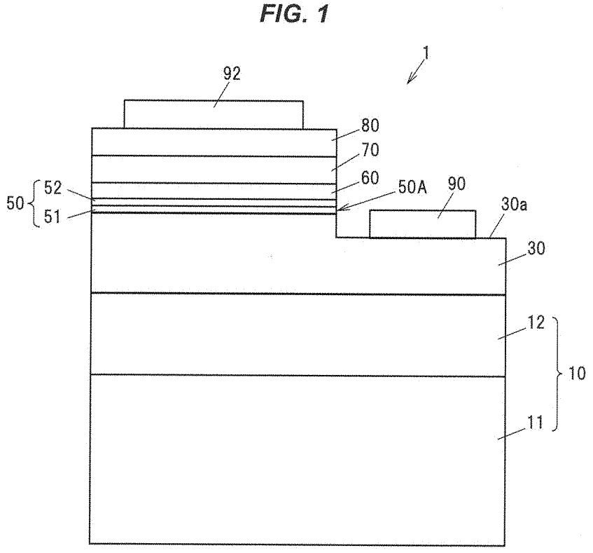

FIG. 1 is a schematic cross-sectional view showing an example configuration of a nitride semiconductor light-emitting element in an embodiment of the invention. A nitride semiconductor light-emitting element 1 (hereinafter, also simply referred to as “light-emitting element 1”) includes, e.g., laser diode or light-emitting diode (LED). In the present embodiment, a light-emitting diode (LED) which emits ultraviolet light at a central wavelength of 290 nm to 360 nm (preferably, 295 nm to 355 nm, more preferably 300 nm to 350 nm) will be described as an example of the light-emitting element 1.

As shown in FIG. 1, the light-emitting element 1 includes a substrate 10, an n-type cladding layer 30, an active layer 50 including a barrier layer 51 and a well layer 52, an electron blocking layer 60, a p-type cladding layer 70, a p-type contact layer 80, an n-side electrode 90 and a p-side electrode 92.

The semiconductor which can be used to form the light-emitting element 1 is, e.g., a binary or ternary group III nitride semiconductor which is expressed by AlₓGa₁₋ₓN (0≤x≤1). In addition, nitrogen (N) may be partially substituted with phosphorus (P), arsenic (As), antimony (Sb) or bismuth (Bi), etc.

The substrate 10 includes, e.g., a sapphire (Al₂O₃) substrate 11 and a buffer layer 12 formed on the sapphire substrate 11. The buffer layer 12 is made of aluminum nitride (AlN). Instead of such a configuration, e.g., an AlN substrate made of only AlN may be used as the substrate 10, and in this case, the buffer layer 12 may not be necessarily included. In other words, a surface of the substrate 10 (an uppermost surface) is made of AlN.

The n-type cladding layer 30 is formed on the substrate 10. The n-type cladding layer 30 is a layer made of AlGaN with n-type conductivity (hereinafter, also simply referred to as “n-type AlGaN”) and is, e.g., an Al_{q}Ga_{1-q}N layer (0≤q≤1) doped with silicon (Si) as an n-type impurity. Alternatively, germanium (Ge), selenium (Se), tellurium (Te) or carbon (C), etc., may be used as the n-type impurity.

The n-type cladding layer 30 has a thickness of about 1 μm to 4 μm and is, e.g., about 3 μm in thickness. The n-type cladding layer 30 may have a single layer structure or may have a multilayer structure. An Al composition ratio (also called “Al content” or “Al mole fraction”) in n-type AlGaN constituting the n-type cladding layer 30 is preferably not more than 50% (0≤q≤0.5).

The active layer 50 is formed on the n-type cladding layer 30. The active layer 50 includes a single quantum well structure 50A composed of one barrier layer 51 located on the n-type cladding layer 30-side and one well layer 52 located on the electron blocking layer 60 (described later)-side (i.e., on the opposite side to the n-type cladding layer 30 in the thickness direction). In addition, the active layer 50 is configured to have a band gap of not less than 3.4 eV so that ultraviolet light at a wavelength of not more than 360 nm (preferably, not more than 355 nm) is output.

The barrier layer 51 is made of AlᵣGa₁₋ᵣN (0≤r≤1). The Al composition ratio in AlGaN constituting the barrier layer 51 (hereinafter, also referred to as “the second Al composition ratio”) is higher than the Al composition ratio in n-type AlGaN constituting the n-type cladding layer 30 (hereinafter, also referred to as “the first Al composition ratio”) (i.e., q≤r≤1). The second Al composition ratio is preferably not less than 50% (0.5≤r≤1), more preferably, 60% to 90%. The barrier layer 51 has a thickness in a range of, e.g., 5 nm to 50 nm.

The well layer 52 is made of AlₛGa₁₋ₛN (0≤s≤1, r>s). The Al composition ratio in AlGaN constituting the well layer 52 (hereinafter, also referred to as “the third Al composition ratio”) is lower than the first Al composition ratio. The third Al composition ratio is preferably not more than 40% (0≤s≤0.4). The well layer 52 has a thickness in a range of, e.g., 1 nm to 5 nm.

The arrangement of the one barrier layer 51 and the one well layer 52 in the quantum well structure 50A are not limited to that described above, and the arrangement order may be reversed from that described above.

The electron blocking layer 60 is formed on the active layer 50. The electron blocking layer 60 is a layer made of AlGaN with p-type conductivity (hereinafter, also simply referred to as “p-type AlGaN”). The electron blocking layer 60 has a thickness of about 1 nm to 30 nm. The Al composition ratio in AlGaN constituting the electron blocking layer 60 (hereinafter, also referred to as “the fourth Al composition ratio”) is higher than the second Al composition ratio. The electron blocking layer 60 may additionally include a layer made of AlN. The electron blocking layer 60 is not necessarily limited to a p-type semiconductor layer and may be an undoped semiconductor layer.

The p-type cladding layer 70 is formed on the electron blocking layer 60. The p-type cladding layer 70 is a layer made of p-type AlGaN and is, e.g., an AlₜGa₁₋ₜN cladding layer (0≤t≤1) doped with magnesium (Mg) as a p-type impurity. Alternatively, zinc (Zn), beryllium (Be), calcium (Ca), strontium (Sr) or barium (Ba), etc., may be used as the p-type impurity. The p-type cladding layer 70 has a thickness of about 10 nm to 1000 nm and is, e.g., about 50 nm to 800 nm in thickness.

The p-type contact layer 80 is formed on the p-type cladding layer 70. The p-type contact layer 80 is, e.g., a p-type GaN layer doped with a high concentration of impurity such as Mg.

The n-side electrode 90 is formed on a certain region of the n-type cladding layer 30. The n-side electrode 90 is made of, e.g., a multilayered film formed by sequentially stacking titanium (Ti), aluminum (Al), Ti and gold (Au) on the n-type cladding layer 30.

The p-side electrode 92 is formed on the p-type contact layer 80. The p-side electrode 92 is made of, e.g., a multilayered film formed by sequentially stacking nickel (Ni) and gold (Au) on the p-type contact layer 80.

(Method for Manufacturing Nitride Semiconductor Light-Emitting Element 1)

Next, a method for manufacturing the light-emitting element 1 will be described. Firstly, the substrate 10 with the outermost surface made of AlN is formed by growing the buffer layer 12 on the sapphire substrate 11 at high temperature. Next, the n-type cladding layer 30, the active layer 50, the electron blocking layer 60 and the p-type cladding layer 70 are grown on the substrate 10 at high temperature while decreasing the temperature in a stepwise manner in this order, thereby forming a disc-shaped nitride semiconductor stacked body (also called “wafer”) with a predetermined diameter (e.g., 50 mm).

The n-type cladding layer 30, the active layer 50, the electron blocking layer 60 and the p-type cladding layer 70 can be formed by a well-known epitaxial growth method such as Metal Organic Chemical Vapor Deposition (MOCVD) method, Molecular Beam Epitaxy (MBE) method, or Halide Vapor Phase Epitaxy (HVPE) method. In addition, the Al composition ratio of each layer is controlled to have an intended value by adjusting compositions, etc., of trimethylaluminum (TMA) and trimethylgallium (TMG), etc., which constitute source gases.

Next, a mask is formed on the p-type cladding layer 70. Then, the active layer 50, the electron blocking layer 60 and the p-type cladding layer 70 are removed in the exposed region in which the mask is not formed. The active layer 50, the electron blocking layer 60 and the p-type cladding layer 70 can be removed by, e.g., plasma etching.

The n-side electrode 90 is formed on an exposed surface 30a of the n-type cladding layer 30 (see FIG. 1), and the p-side electrode 92 is formed on the p-type contact layer 80 after removing the mask. The n-side electrode 90 and the p-side electrode 92 can be formed by, e.g., a well-known method such as electron beam evaporation method or sputtering method. The light-emitting element 1 shown in FIG. 1 is obtained by cutting this wafer into pieces with a predetermined dimension.

(Measurement Result 1)

Next, an example of the result obtained by measuring emission output of the light-emitting element 1 in Example of the embodiment of the invention will be described. The measurement result 1 shows a relation between the number of well and barrier layers and emission output when measured at similar wavelengths (315±10 nm). The light-emitting element 1 in Example includes the single quantum well structure 50A (hereinafter, also referred to as “SQW (Single Quantum Well)”) as the active layer 50, as described above.

On the other hand, the light-emitting elements in Comparative Examples 1 and 2 include a multiple quantum well layer formed by alternately stacking plural barrier layers 51 and plural well layers 52 (hereinafter, also referred to as “MQW (Multiple Quantum Well)”) as the active layer 50. That is, the number of the quantum well structures 50A is different between the light-emitting element 1 in Example and the light-emitting elements in Comparative Examples 1 and 2.

In particular, the light-emitting element in Comparative Example 1 has three quantum well structures 50A which are provided so that three barrier layers 51 and three well layers 52 are stacked alternately (hereinafter, also referred to as “3QW”). The light-emitting element in Comparative Example 2 has two quantum well structures 50A which are provided so that two barrier layers 51 and two well layers 52 are stacked alternately (hereinafter, also referred to as “2QW”). The conditions other than the number of the quantum well structures 50A (e.g., the composition and thickness, etc., of each layer) are the same for the light-emitting element 1 in Example and the light-emitting elements in Comparative Examples 1 and 2.

The measurement results in Example and Comparative Examples are shown in Table 1. Emission wavelength (nm) is a wavelength when the emission output was measured. Emission output (arbitrary unit) can be measured by various known methods, and the method used in this Example was, as an example, a method in which In (indium) electrodes were respectively attached to the center portion and edge portion of one wafer, a predetermined current was supplied to the electrodes to make the wafer emit light from the center portion, and the emitted light was measured by a photodetector set at a predetermined position. The magnitude of the current supplied was 20 mA in each measurement.

TABLE 1
Measurement result

| | Quantum well | Emission | Emission output |
|---|---|---|---|
| Examples | structures (Number) | wavelength (nm) | (arbitrary unit) |
| Comparative | 3 (3QW) | 316.78 | 0.56 |
| Example 1 | | | |
| Comparative | 2 (2QW) | 320.75 | 0.15 |
| Example 2 | | | |
| Example | 1 (1QW) | 314.40 | 0.80 |

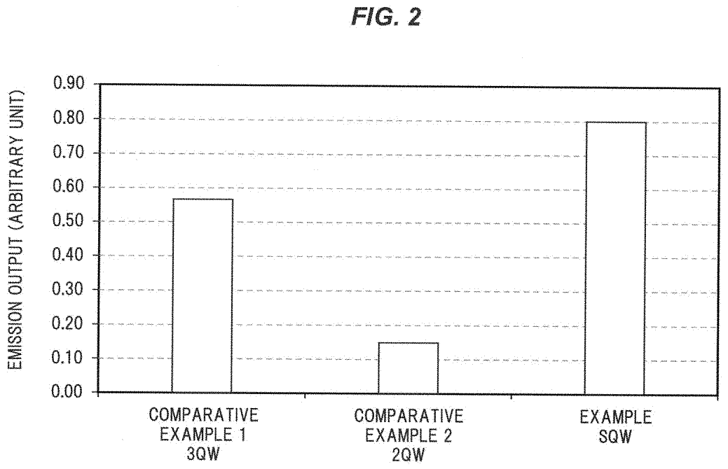

FIG. 2 is a diagram in which emission outputs of the light-emitting element 1 in Example and the light-emitting elements in Comparative Examples 1 and 2 shown in Table 1 are represented as a bar chart. As shown in Table 1 and FIG. 2, while the emission outputs in Comparative Example 1 and Comparative Example 2 are only 0.56 and 0.15, the emission output obtained in Example was 0.80. In other words, the emission output obtained in Example was about 1.4 times that of Comparative Example 1 and about 5.3 times that of Comparative Example 2.

As a result of comparing the emission outputs of the light-emitting elements having two or three quantum well structures 50A and the light-emitting element 1 having the single quantum well structure 50A, the emission output of the light-emitting element 1 having the single quantum well structure 50A was the highest as described above. This shows that providing one quantum well structure 50A achieves higher emission output than the configuration in which plural (two or three) quantum well structures 50A are provided. The emission output of the light-emitting element having two quantum well structures 50A was the lowest among the three light-emitting elements.

(Measurement Result 2)

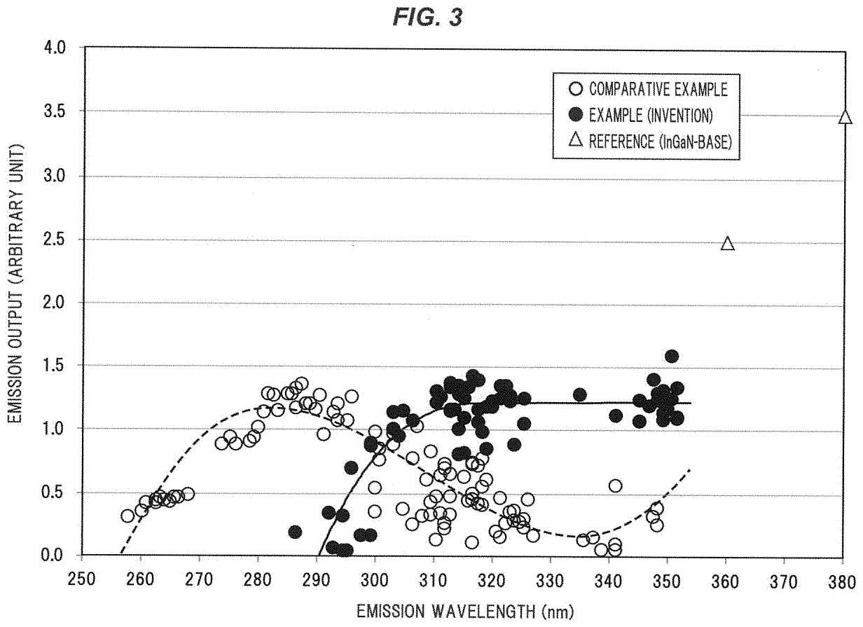

Next, a relation between emission wavelength and emission output will be described in reference to FIG. 3. FIG. 3 is a diagram illustrating an example of the relation between emission wavelength and emission output of the light-emitting elements in Example and Comparative Example. The method used in this experiment was, as an example, a method in which In (indium) electrodes were respectively attached to the center portion and edge portion of one wafer, a predetermined current was supplied to the electrodes to make the wafer emit light from the center portion, and the emitted light was measured by a photodetector set at a predetermined position. The emission output of the light-emitting elements 1 in Example is emission output obtained from the center of the wafer. The light-emitting elements in Comparative Example had plural (two to four) quantum well structures 50A. Seventy-one light-emitting elements 1 in Example and ninety-eight light-emitting elements in Comparative Example were prepared as samples subjected to measurement.

In FIG. 3, the filled circles indicate the measurement results of the light-emitting elements 1 in Example and the open circles indicate the measurement results of the light-emitting elements in Comparative Example. Then, (two) triangles indicate the measurement results of InGaN-based nitride semiconductor light-emitting elements as reference. In addition, the solid line of FIG. 3 is a fitted curve for the data indicated by the filled circles and the dotted line is a fitted curve for the data indicated by the open circles.

As shown in FIG. 3, the emission output of the light-emitting elements in Comparative Example increases with an increase in the emission wavelength from about 255 nm to about 285 nm, has a local maximum value at around 285 nm, decreases with an increase in the emission wavelength from about 285 nm to about 335 nm, has a local minimum value at around 335 nm, and increases again in the emission wavelength range of not less than about 335 nm (see the dotted line). In other words, the data of emission wavelength (nm) vs emission output (arbitrary unit) for the light-emitting elements in Comparative Example forms a substantially cubic function curve. As described above, the light-emitting elements in Comparative Example shows a tendency that the emission output in the emission wavelength range of about 280-290 nm to 350-360 nm decreases unlike the emission output in the other emission wavelength range.

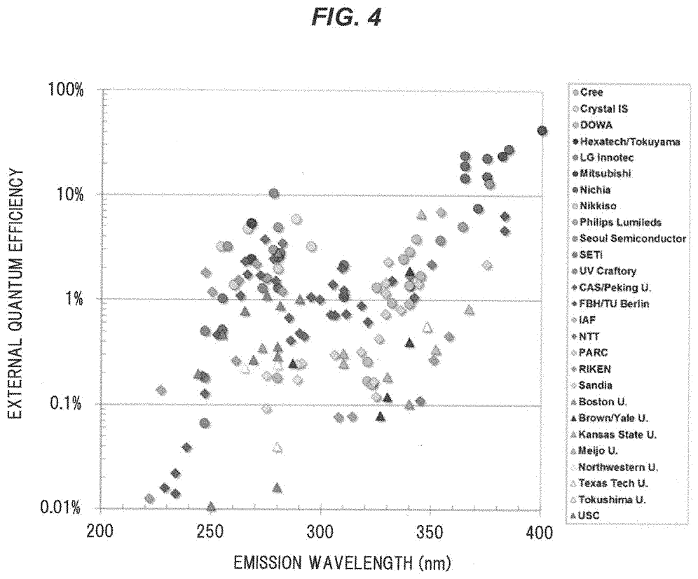

Light-emitting elements manufactured by various companies in Comparative Example also show the same tendency, as shown in FIG. 4. FIG. 4 is the data extracted from FIG. 1.1 shown in “III-Nitride Ultraviolet Emitters Technology and Applications” by Kneissl, Michael, Rass, Jens, published by Springer, 2016, ISBN:978-3-319-24098-5.

On the other hand, the emission output of the light-emitting elements 1 in Example increases with an increase in the emission wavelength from about 290 nm to about 315 nm, and then has a stable value of between 1.0 to 1.5 in the emission wavelength range from about 315 nm to about 355 nm (see the solid line). This shows that the emission output of the light-emitting elements 1 in Example increases in the wavelength range in which the emission output of the light-emitting elements in Comparative Example decreases (in the range of about 280-290 nm to 350-360 nm).

### Functions and Effects of the Embodiment

As described above, the light-emitting element 1 in the embodiment of the invention is configured that the single quantum well structure 50A composed of one barrier layer 51 and one well layer 52 is provided between the n-type cladding layer 30 and the electron blocking layer 60. As a result, the emission output of the light-emitting element 1 emitting ultraviolet light at a central wavelength of 290 nm to 360 nm (preferably 295 nm to 355 nm, more preferably 300 nm to 350 nm) can be improved.

### Summary of the Embodiment

Technical ideas understood from the embodiment will be described below citing the reference numerals, etc., used for the embodiment. However, each reference numeral, etc., described below is not intended to limit the constituent elements in the claims to the members, etc., specifically described in the embodiment.

[1] A nitride semiconductor light-emitting element (1) comprising stacked AlGaN-based nitride semiconductors and being configured to emit ultraviolet light at a central wavelength of 290 nm to 360 nm, the nitride semiconductor light-emitting element (1) comprising: an n-type cladding layer (30) comprising n-type AlGaN; and an active layer (50) provided on the n-type cladding layer (30) and comprising a single quantum well structure (50A) comprising one barrier layer (51) comprising AlGaN and one well layer (52) comprising AlGaN with an Al composition ratio lower than an Al composition ratio of the AlGaN constituting the one barrier layer (51).

[2] The nitride semiconductor light-emitting element (1) described in [1], wherein the one barrier layer (51) is located on a side of the n-type cladding layer (30) in the single quantum well structure (50A) and the one well layer (52) is located on an opposite side to the n-type cladding layer (30) in the single quantum well structure (50A).

[3] The nitride semiconductor light-emitting element (1) described in [1] or [2], wherein the one barrier layer (51) comprises AlGaN with an Al composition ratio higher than an Al composition ratio of the n-type AlGaN.

[4] The nitride semiconductor light-emitting element (1) described in [1] or [2], further comprising: a substrate (10) being located under the n-type cladding layer (30) and having a surface comprising AlN.

[5] The nitride semiconductor light-emitting element (1) described in [3], further comprising: a substrate (10) being located under the n-type cladding layer (30) and having a surface comprising AlN.

[6] A method for manufacturing a nitride semiconductor light-emitting element (1) configured to emit ultraviolet light at a central wavelength of 290 nm to 360 nm, the method comprising: forming an n-type cladding layer (30) comprising n-type AlGaN on a substrate (10); and forming, on the n-type cladding layer (30), an active layer (50) comprising a single quantum well structure (50A) comprising one barrier layer (51) comprising AlGaN and one well layer (52) comprising AlGaN with an Al composition ratio lower than an Al composition ratio of the AlGaN constituting the one barrier layer (51).

### INDUSTRIAL APPLICABILITY

Provided is a nitride semiconductor light-emitting element with improved luminous efficiency in a specific emission wavelength range, and a method for manufacturing the same.

### REFERENCE SIGNS LIST

1: nitride semiconductor light-emitting element (light-emitting element)

10: substrate

11: sapphire substrate

30: n-type cladding layer

50: active layer

50A: single quantum well structure

51: barrier layer

52: well layer

1. A nitride semiconductor light-emitting element comprising stacked AlGaN-based nitride semiconductors and being configured to emit ultraviolet light at a central wavelength of 290 nm to 360 nm, the nitride semiconductor light-emitting element comprising:
an n-type cladding layer comprising n-type AlGaN; and
an active layer provided on the n-type cladding layer and comprising a single quantum well structure comprising one barrier layer comprising AlGaN and one well layer comprising AlGaN with an Al composition ratio lower than an Al composition ratio of the AlGaN constituting the one barrier layer.

2. The nitride semiconductor light-emitting element according to claim 1, wherein the one barrier layer is located on a side of the n-type cladding layer in the single quantum well structure and the one well layer is located on an opposite side to the n-type cladding layer in the single quantum well structure.

3. The nitride semiconductor light-emitting element according to claim 1, wherein the one barrier layer comprises AlGaN with an Al composition ratio higher than an Al composition ratio of the n-type AlGaN.

4. The nitride semiconductor light-emitting element according to claim 1, further comprising:
a substrate being located under the n-type cladding layer and having a surface comprising AlN.

5. The nitride semiconductor light-emitting element according to claim 3, further comprising:
a substrate being located under the n-type cladding layer and having a surface comprising AlN.

6. A method for manufacturing a nitride semiconductor light-emitting element configured to emit ultraviolet light at a central wavelength of 290 nm to 360 nm, the method comprising:
forming an n-type cladding layer comprising n-type AlGaN on a substrate; and
forming, on the n-type cladding layer, an active layer comprising a single quantum well structure comprising one barrier layer comprising AlGaN and one well layer comprising AlGaN with an Al composition ratio lower than an Al composition ratio of the AlGaN constituting the one barrier layer.

7. The nitride semiconductor light-emitting element according to claim 2, wherein the one barrier layer comprises AlGaN with an Al composition ratio higher than an Al composition ratio of the n-type AlGaN.

8. The nitride semiconductor light-emitting element according to claim 2, further comprising:
a substrate being located under the n-type cladding layer and having a surface comprising AlN.
